(19) United States
(12) Patent Application Publication
(10) Pub. No.: US 2024/0175926 A1
(43) Pub. Date: May 30, 2024

(54) BATTERY HEALTH DETECTION BASED ON NATURAL SOAKING RESPONSE

(71) Applicant: GM Global Technology Operations LLC, Detroit, MI (US)

(72) Inventors: Ibrahim Haskara, Macomb, MI (US); Yusheng Zou, Northville, MI (US); Chengwu Duan, Shanghai (CN)

(21) Appl. No.: 18/179,569

(22) Filed: Mar. 7, 2023

(30) Foreign Application Priority Data
Nov. 30, 2022 (CN) 202211516916.3

(51) Int. Cl. G01R 31/367; G01R 31/3835; G01R 31/396

(52) U.S. Cl. CPC G01R 31/367; G01R 31/3835; G01R 31/396

(57) ABSTRACT

Embodiments include battery health detection based on natural soaking response. Aspects include measuring a plurality of characteristics of a battery pack at a first time and measuring the plurality of characteristics of the battery pack at a second time that is after the first time. Aspects also include inputting the plurality of characteristics and a difference between the first time and the second time into a trained model for identifying anomalies and determining, based on the trained model, whether the battery pack includes an anomaly. Based on a determination that the battery pack includes the anomaly, aspects include flagging the battery pack as containing the anomaly.

### CROSS-REFERENCE TO RELATED APPLICATIONS

This application claims priority to Chinese Patent Application No. 202211516916.3, filed Nov. 30, 2022, the contents of which are incorporated by reference herein in their entirety.

### INTRODUCTION

The disclosure relates to battery health detection. More specifically, the disclosure relates to methods and systems for detecting the health of a battery for a vehicle based on a natural soaking response.

In general, battery soaking is the process of allowing an assembled battery pack to remain unconnected from an external load for a period of time. In some cases, battery soaking is deliberately performed for a specified period of time. In other cases, a natural soaking of the battery occurs between the completion of the manufacturing of the battery and the connection of the battery to an external load (i.e., the natural soaking period is the time between completion of the manufacturing of the battery pack and the battery pack being connected to a vehicle). In some cases, during the battery soaking process, the battery may undergo changes that can be indicative of problems with the battery.

### SUMMARY

In one exemplary embodiment, a method for detecting an anomaly in a battery for a vehicle based on natural soaking is provided. The method includes measuring a plurality of characteristics of a battery pack at a first time and measuring the plurality of characteristics of the battery pack at a second time that is after the first time. The method also includes inputting the plurality of characteristics and a difference between the first time and the second time into a trained model for identifying anomalies and determining, based on the trained model, whether the battery pack includes an anomaly. Based on a determination that the battery pack includes the anomaly, the method includes flagging the battery pack as containing the anomaly.

In addition to the one or more features described herein the first time is after completion of a manufacturing of the battery pack.

In addition to the one or more features described herein the second time is before the battery pack is connected to an external load.

In addition to the one or more features described herein the plurality of characteristics of the battery pack include one or more of an average voltage of the battery pack, a voltage of each cell of the battery pack, an average temperature of the battery pack, and a voltage drop of cell of the battery pack.

In addition to the one or more features described herein the method also includes computing one or more features for the battery pack based on the measured values and inputting the one or more features into the trained model.

In addition to the one or more features described herein the one or more features include one or more of an average voltage of the battery pack, a voltage range of the battery pack, a voltage drop over a natural soaking time for the battery pack, a rate of voltage drop over the natural soaking time for the battery pack, a change in a temperature of the battery pack over the natural soaking time, and a rate of change in the temperature of the battery pack over the natural soaking time.

In addition to the one or more features described herein the method also includes identifying one or more cells of the battery pack that include the anomaly based on a determination that the battery pack includes the anomaly.

In addition to the one or more features described herein the method also includes flagging the one or more cells of the battery pack that include the anomaly for inspection.

In addition to the one or more features described herein the trained model for identifying anomalies is trained based on historical data regarding changes to the plurality of characteristics for a plurality of battery packs during corresponding natural soaking periods and an observed failure data for the plurality of battery packs.

In addition to the one or more features described herein the method also includes dynamically updating the trained model as updated failure rate data is obtained.

In one exemplary embodiment, a computer program product having a computer-readable storage medium having program instructions embodied therewith for detecting an anomaly in a battery for a vehicle based on a natural soaking is provided. The program instructions executable by a processor to cause the processor to perform a method. The method includes measuring a plurality of characteristics of a battery pack at a first time and measuring the plurality of characteristics of the battery pack at a second time that is after the first time. The method also includes inputting the plurality of characteristics and a difference between the first time and the second time into a trained model for identifying anomalies and determining, based on the trained model, whether the battery pack includes an anomaly. Based on a determination that the battery pack includes the anomaly, the method includes flagging the battery pack as containing the anomaly.

In addition to the one or more features described herein the first time is after completion of a manufacturing of the battery pack.

In addition to the one or more features described herein the second time is before the battery pack is connected to an external load.

In addition to the one or more features described herein the plurality of characteristics of the battery pack include one or more of an average voltage of the battery pack, a voltage of each cell of the battery pack, an average temperature of the battery pack, and a voltage drop of cell of the battery pack.

In addition to the one or more features described herein the method also includes computing one or more features for the battery pack based on the measured values and inputting the one or more features into the trained model.

In addition to the one or more features described herein the one or more features include one or more of an average voltage of the battery pack, a voltage range of the battery pack, a voltage drop over a natural soaking time for the battery pack, a rate of voltage drop over the natural soaking time for the battery pack, a change in a temperature of the battery pack over the natural soaking time, and a rate of change in the temperature of the battery pack over the natural soaking time.

In addition to the one or more features described herein the method also includes identifying one or more cells of the battery pack that include the anomaly based on a determination that the battery pack includes the anomaly.

In addition to the one or more features described herein the method also includes flagging the one or more cells of the battery pack that include the anomaly for inspection.

In addition to the one or more features described herein the trained model for identifying anomalies is trained based on historical data regarding changes to the plurality of characteristics for a plurality of battery packs during corresponding natural soaking periods and an observed failure data for the plurality of battery packs.

In addition to the one or more features described herein the method also includes dynamically updating the trained model as updated failure rate data is obtained.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a schematic diagram of a vehicle for use in conjunction with one or more embodiments of the present disclosure;

FIG. 2 is a flowchart illustrating a method for detecting an anomaly in a battery for a vehicle based on a natural soaking response in accordance with an exemplary embodiment;

FIG. 3 is a flowchart illustrating a method for training a machine learning model for identifying anomalies in a battery pack in accordance with an exemplary embodiment;

FIG. 4 is a flowchart illustrating a method for identifying one or more battery cells of a battery pack that include an anomaly based on a natural soaking response in accordance with an exemplary embodiment; and

FIG. 5 is a flowchart illustrating a method for adjusting an outlier rate of a machine learning model for detecting an anomaly in a battery pack based on a natural soaking response in accordance with an exemplary embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features.

Turning now to an overview of the aspects of the disclosure, embodiments of the disclosure include methods for identifying defects in a battery pack based on a natural soaking response of the battery. In exemplary embodiments, a plurality of characteristics of a battery pack are measured before and after a natural soaking time of the battery pack and changes in the plurality of characteristics are used to identify potential problems with the battery pack. In exemplary embodiments, machine learning methods are used to analyze the changes in the characteristics of the battery pack over the natural soaking time and to predict whether a battery pack includes a defect that could lead to abnormal behavior, (i.e., premature failure, excessive discharge, or the like of the battery).

In exemplary embodiments, once it is determined that a battery pack includes an anomaly further analysis is performed to identify which cells of the battery pack include the anomaly. In one embodiment, the data corresponding to each of the plurality of characteristics for each cell of the battery pack, from before and after the natural soaking time, are input into a trained machine learning model to identify the cells of the battery pack that include the anomaly. Once the cell of the battery pack that contains the anomaly is identified, that cell can be replaced or repaired.

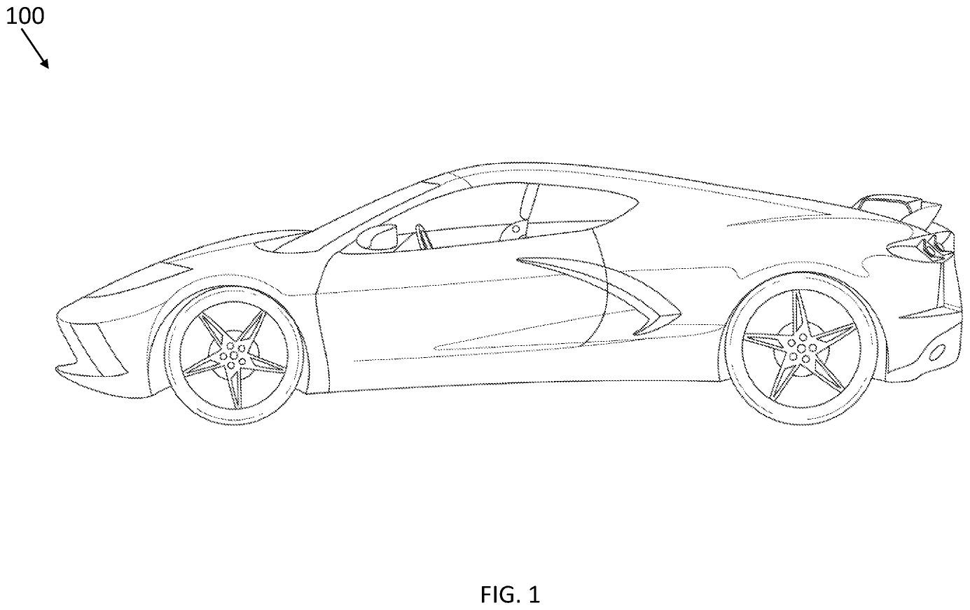

Referring now to FIG. 1, a schematic diagram of a vehicle 100 for use in conjunction with one or more embodiments of the present disclosure is shown. The vehicle 100 includes a battery (not shown). In one embodiment, the vehicle 100 is a hybrid vehicle that utilizes both an internal combustion engine and an electric motor powered by a battery. In another embodiment, the vehicle 100 is an electric vehicle that only utilizes electric motors that are powered by one or more batteries.

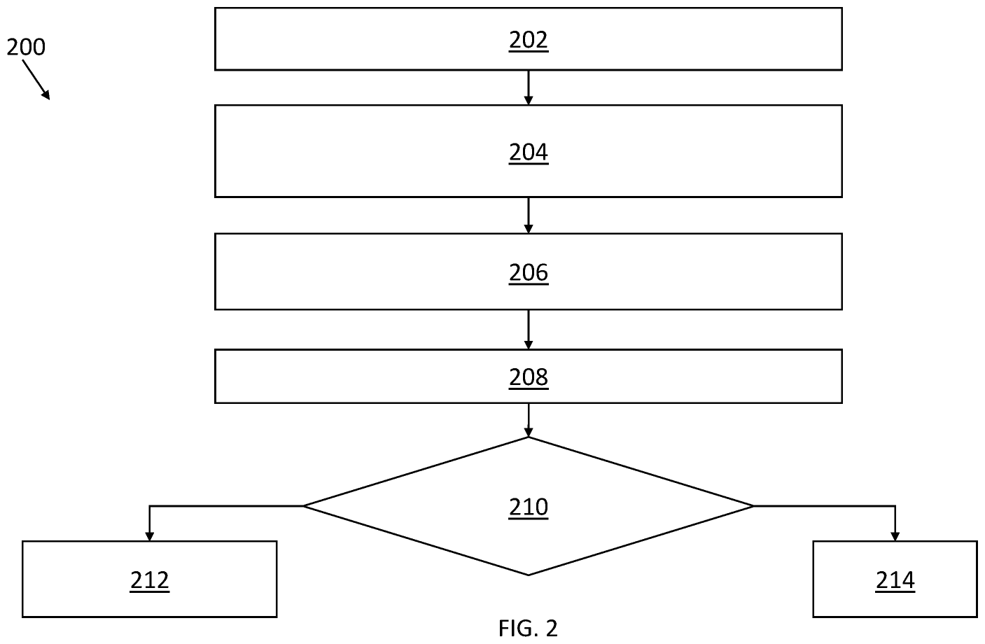

Referring now to FIG. 2 a flowchart illustrating a method 200 for detecting an anomaly in a battery for a vehicle based on a natural soaking response in accordance with an exemplary embodiment is shown.

At block 202, the method 200 includes measuring a plurality of characteristics of a battery pack at a first time. In exemplary embodiments, the first time is after the completion of the manufacturing of the battery pack and before the battery pack is connected to an external load. In exemplary embodiments, the plurality of characteristics of a battery pack include, but are not limited to, one or more of an average voltage of the battery pack, a voltage of each cell of the battery pack, an average temperature of the battery pack, and a voltage drop of each cell of the battery pack. Next, at block 204, the method 200 includes measuring the plurality of characteristics of the battery pack at a second time. In exemplary embodiments, the second time is after the first time and the second time is before the battery pack is connected to an external load, (i.e., connected to an electric vehicle). The time period between the first time and the second time is referred to herein as the natural soaking time.

In exemplary embodiments, the plurality of characteristics of a battery pack may be collected at multiple time periods between completion of the manufacturing of the battery pack and the connection of an external load to the battery pack. In cases where more than two measurements of the plurality of characteristics of the battery pack are collected the first time will be selected to be the earliest time at which the plurality of characteristics of the battery pack are collected and the second time will be the latest time at which plurality of characteristics of the battery pack are collected.

At block 206, the method 200 includes inputting the measured values and a difference between the first time and the second time (i.e., a duration of the natural soaking time) into a trained model for identifying anomalies in a battery pack. In exemplary embodiments, the measured data is analyzed and one or more features for the battery pack are computed based on the measured values. These computed features are then input into the machine learning model. The one or more features include, but are not limited to, an average pack voltage, a voltage range of the battery pack, a voltage drop over the natural soaking time for the battery pack, a rate of voltage drop over the natural soaking time for the battery pack, a change in temperature of the battery pack over the natural soaking time, and a rate of change in temperature of the battery pack over the natural soaking time. In exemplary embodiments, one or more of these features may be calculated individually for each cell of the battery pack and/or for modules comprising a plurality of connected cells in addition to being calculated for the battery pack as a whole.

In exemplary embodiments, the one or more features that the machine learning model uses include the voltage drop over the natural soaking time for the battery pack, which is calculated as Vₛ−Vₒ, where Vₛ is the voltage at the start of the soaking period (i.e., the voltage at the first time) and Vₒ is the voltage at the end of the soaking period (i.e., the voltage at the second time). In addition, the one or more features that the machine learning model uses include the rate of voltage drop over the natural soaking time for the battery pack, which is calculated as

$$( \frac{{V}_{s} - {V}_{o}}{{t}_{o} - {t}_{s}} )$$

where tₛ is a timestamp corresponding to the at the first time at the start of the natural soaking period and tₒ is a timestamp at the second time at the end of the natural soaking period. The one or more features that the machine learning model uses include a mean voltage drop rate, which is computed as

$$\frac{{mean}_{cell} ( {V}_{s} ) - {mean}_{cell} ( {V}_{o} )}{{t}_{o} - {t}_{s}} .$$

In exemplary embodiments, the one or more features that the machine learning model uses can include a mean voltage, which is computed as

$${mean}_{cell} ( {V}_{o} ) ,$$

a voltage range, which is computed as

$${max}_{cell} ( {V}_{o} ) - {min}_{cell} ( {V}_{o} ) ,$$

a maximum voltage drop rate, which is computed as

$${max}_{cell} ( \frac{{V}_{s} - {V}_{o}}{{t}_{o} - {t}_{s}} ) ,$$

and a maximum voltage drop, which is computed as

$${max}_{cell} ( {V}_{s} - {V}_{o} ) .$$

At block 208, the method 200 includes obtaining, based on the trained model, a score for the battery pack. In exemplary embodiments, the model is configured to calculate a score that is positively correlated to the predicted health of the battery pack, (i.e., a lower score is indicative that the battery pack may include an anomaly). The method 200 also includes determining whether the battery pack includes an anomaly based on the calculated score, at decision block 210. In exemplary embodiments, determining whether the battery pack includes an anomaly based on the calculated score includes comparing, by the trained model, the score to a threshold level. In exemplary embodiments, the threshold level is initially determined based on historical failure rates. In one embodiment, the threshold level is dynamically adjusted based on observed failure rates of newly created battery packs. In another embodiment, this threshold value is determined by the model trained and used, for example, the classification boundary.

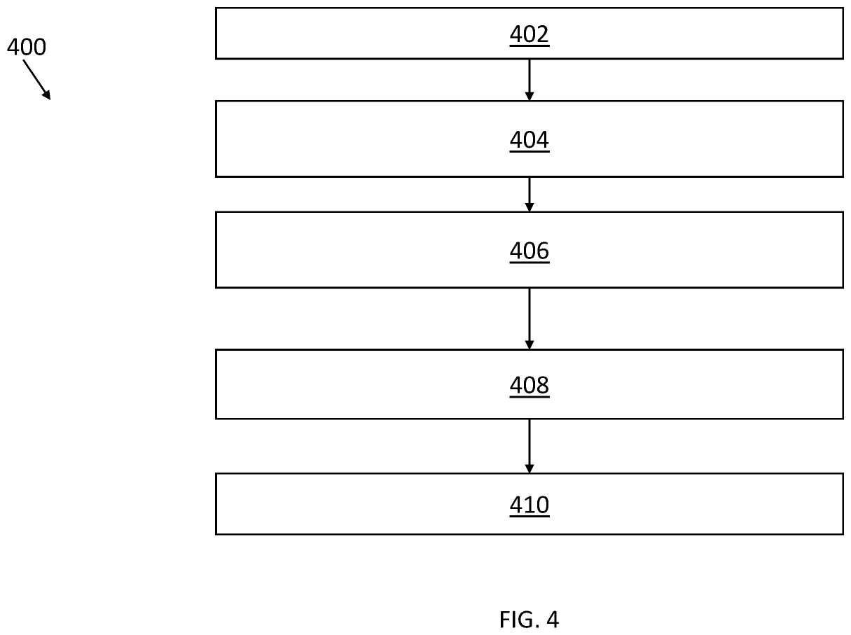

Based on a determination that the battery pack includes an anomaly, the method 200 proceeds to block 212, and marks the battery pack as including an anomaly. In one embodiment, once a battery pack is marked as having an anomaly, the data collected for each cell of the battery pack is analyzed to identify one or more cells of the battery pack that include the anomaly, as described in more detail with reference to FIG. 4. Otherwise, the method 200 proceeds to block 214 and marks the battery as normal.

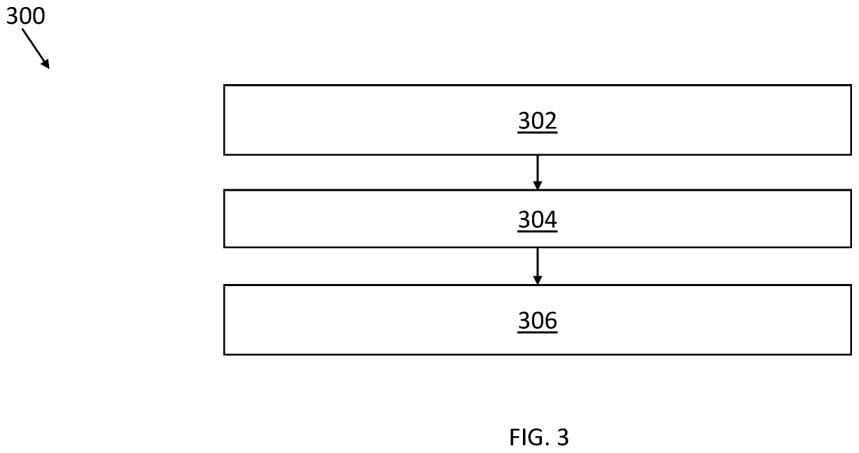

Referring now to FIG. 3 a flowchart illustrating a method 300 for training a machine learning model for identifying anomalies in a battery pack in accordance with an exemplary embodiment is shown. At block 302, the method 300 includes obtaining historical data regarding a plurality of characteristics of a plurality of battery packs before and after corresponding soaking periods (i.e., between a first time and a second time). In exemplary embodiments, training the machine learning model also includes computing one or more features for the plurality of battery packs based on the obtained historical data.

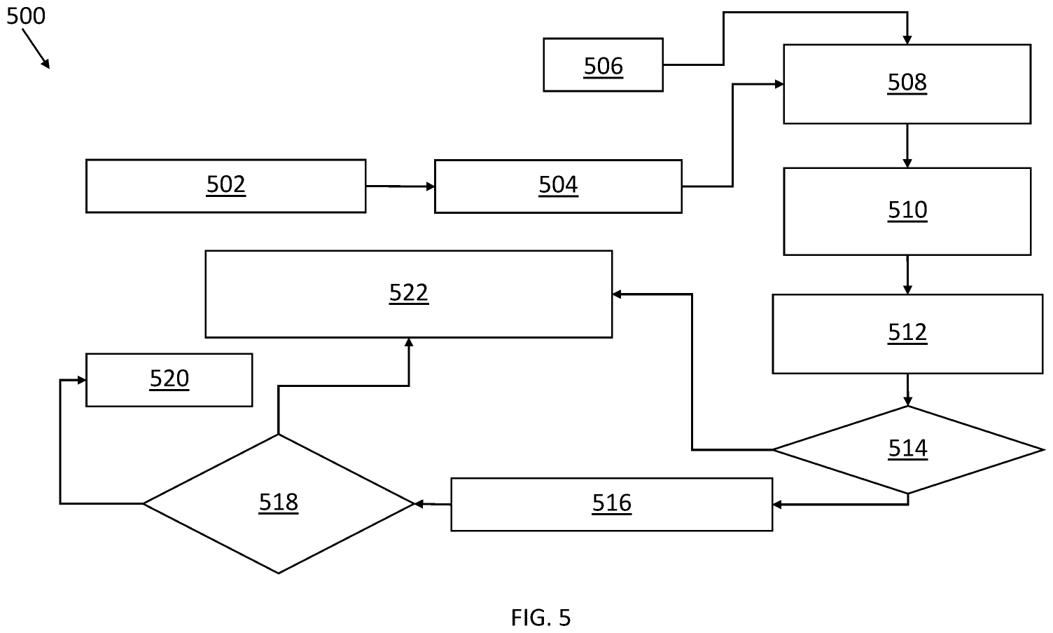

At block 304, the method 300 also includes obtaining observed failure data for the plurality of battery packs. In exemplary embodiments, the observed failure data includes a historical outlier rate for the plurality of battery packs, (i.e., the rate of premature failure of the battery packs). In exemplary embodiments, the historical outlier rate is obtained from historical manufacturing data, reflecting the faulty packs identified at assembly and in warranty claims. In exemplary embodiments, the machine learning model is dynamically updated based on newly received observed failure data, as explained in more detail with reference to FIG. 5.

At block 306, the method 300 includes training the machine learning model for identifying anomalies in a battery pack based on the obtained data. In exemplary embodiments, the trained machine learning model is a one-class support vector machine (SVM), which is an unsupervised model that learns a decision function to determine whether a battery pack includes an anomaly, (i.e., classifying new characteristic data as similar or different to the training set). In other embodiments, the trained machine learning model is a multi-class SVM.

Referring now to FIG. 4 a flowchart illustrating a method 400 for identifying one or more battery cells of a battery pack that include an anomaly based on a natural soaking response in accordance with an exemplary embodiment is shown. At block 402, the method 400 includes identifying a battery pack as containing an anomaly. In exemplary embodiments, a method such as the one shown in FIG. 2 is used to identify a battery pack as containing an anomaly. Next, at block 404, the method 400 includes obtaining a plurality of characteristics for each battery cell of the battery pack from before and after a soaking period. The plurality of characteristics for each battery cell of the battery pack include, but are not limited to, an average voltage of the battery cell, a minimum voltage of the battery cell, a maximum voltage of the battery cell, a voltage drop of the battery cell, a voltage drop rate of the battery cell, a temperature of the battery cell, a change in the temperature of the battery cell, and a rate of the change in the temperature of the battery cell.

Next, at block 406, the method 400 includes inputting the plurality of characteristics for each battery cell of the battery pack and in some embodiments the duration of the soaking period into a trained model for identifying anomalies in battery cells. In exemplary embodiments, the trained model for identifying anomalies in battery cells is similar to the trained model for identifying anomalies in a battery pack. In one embodiment, the trained model for identifying anomalies in battery cells is trained based on historical data regarding changes to a plurality of characteristics of a plurality of battery cells during corresponding soaking periods and the observed failure data for the plurality of battery cells. In exemplary embodiments, the trained machine learning model is a one-class support vector machine (SVM), which is an unsupervised model that learns a decision function to determine whether a battery cell includes an anomaly, (i.e., classifying new characteristic data for a battery cell as similar or different to identified battery cells having anomalies in the training set). In other embodiments, the trained machine learning model is a multi-class SVM.

In exemplary embodiments, the battery pack characteristic data collected includes data regarding the performance of each battery cell and the location of each cell within the layout of the battery pack. The location of the cells can be used in combination with the data regarding the performance of each battery cell to identify potential anomalies in the battery pack and/or within specific battery cells.

In one embodiment, machine learning algorithms use both the values and index of the cells (i.e., location of a battery cell within the battery pack) so that a different pattern in the voltage spread within the battery pack can also be obtained. For example, the minimum voltage of a battery cell within the battery pack is just a voltage reading, but the actual voltages or derived voltage drops during natural soaking period over a cell index array provide an extra information in terms of any variational pattern within the voltage array. Another example is that if nearby cells have a propagating deviation, this is an information that machine learning algorithm can identify. Accordingly, data regarding the physical features of the battery cells is captured as an array that includes both the captured data values and the battery cell locations as index values so that more patterns can be extracted an analyzed by the machine learning algorithm.

At block 408, the method 400 includes identifying, based on the trained model, one or more of the battery cells of the battery pack that include an anomaly. Once a battery cell has been identified as having an anomaly, the method 400 proceeds to block 410 and flags the one or more battery cells as containing the anomaly. In exemplary embodiments, flagging the battery cell as containing an anomaly causes an inspection and/or rework of the battery cells by replacing the battery cell in the battery pack or repairing the battery cell in the battery pack.

Referring now to FIG. 5, a flowchart illustrates a method 500 for adjusting an outlier rate of a machine learning model for detecting an anomaly in a battery pack based on a natural soaking response in accordance with an exemplary embodiment. The method 500 begins at block 502 by setting an initial outlier rate to a historical failure data obtained from battery pack manufacturing data. Next, at block 504, the method 500 includes training a classifier of a machine learning model based on a specified outlier rate. At block 506, the method 500 receives data for a newly manufactured battery pack. The newly received data includes the plurality of characteristics of the battery pack from before and after the natural soaking time and the duration of the natural soaking time. In some embodiments, the newly received data is used to tune, or adjust, the outlier rate. In other embodiments, the outlier rate is only adjusted or tuned based on existing data and does not include the newly received data. At block 508, the method 500 includes predicting whether the battery pack includes an anomaly based on the trained classifiers.

At block 510, the method 500 includes calculating a performance metric of the classifier based on the prediction of the classifier and upon the ground truth, (i.e., whether the battery pack actually had an anomaly). The method 500 also includes observing determination distributions and classifier performance, at block 512. At decision block 514 the method 500 determines whether the classifier performance has improved since the outlier rate was last changed. If the classifier performance has improved since the outlier rate was last changed, the method 500 proceeds to block 516 and continues to increase or decrease the outlier rate. Next, at decision block 518, the method 500 determines whether the classifier performance has worsened. If so, the method 500 proceeds to block 520 and ends the tunning of the outlier rate. Otherwise, the method 500 proceeds to block 522. In an exemplary embodiment, at block 522, the method 500 includes increasing the outlier rate based on a determination that the classifier performance is too conservative on a healthy battery pack classification and decreasing the outlier rate based on a determination that there are too many false identifications of anomalies.

As discussed above, once a battery pack has been identified as having an anomaly, the data regarding the cells of the battery pack are analyzed to identify which cells include anomalies. In exemplary embodiments, battery pack level anomaly detection may use data collected for both battery pack level and cell level features. For example, battery pack level anomaly detection can detect whether an average voltage drop rate for the battery pack is much higher than expected. In addition, battery pack level anomaly detection can detect whether there is a specific variation pattern of the voltage drop over the multiple battery cells. The battery cell level anomaly detection analyses and compare cell specific features with one another to pinpoint which cells are behaving different than the rest. In one embodiment, the battery pack level anomaly detection can use both battery pack level data and cell level features although the intended output of the first layer is to identify battery packs with anomalies, whereas the battery cell level anomaly detection only uses battery cell level data to identify battery cell level anomalies.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method comprising:
measuring a plurality of characteristics of a battery pack at a first time;
measuring the plurality of characteristics of the battery pack at a second time that is after the first time;
inputting the plurality of characteristics and a difference between the first time and the second time into a trained model for identifying anomalies;
determining, based on the trained model, whether the battery pack includes an anomaly; and
based on a determination that the battery pack includes the anomaly, flagging the battery pack as containing the anomaly.

2. The method of claim 1, wherein the first time is after completion of a manufacturing of the battery pack.

3. The method of claim 1, wherein the second time is before the battery pack is connected to an external load.

4. The method of claim 1, wherein the plurality of characteristics of the battery pack include one or more of an average voltage of the battery pack, a voltage of each cell of the battery pack, an average temperature of the battery pack, and a voltage drop of cell of the battery pack.

5. The method of claim 1, further comprising computing one or more features for the battery pack based on the measured values and inputting the one or more features into the trained model.

6. The method of claim 5, wherein the one or more features include one or more of an average voltage of the battery pack, a voltage range of the battery pack, a voltage drop over a natural soaking time for the battery pack, a rate of voltage drop over the natural soaking time for the battery pack, a change in a temperature of the battery pack over the natural soaking time, and a rate of change in the temperature of the battery pack over the natural soaking time.

7. The method of claim 1, further comprising identifying one or more cells of the battery pack that include the anomaly based on a determination that the battery pack includes the anomaly.

8. The method of claim 7, further comprising flagging the one or more cells of the battery pack that include the anomaly for inspection.

9. The method of claim 1, wherein the trained model for identifying anomalies is trained based on historical data regarding changes to the plurality of characteristics for a plurality of battery packs during corresponding natural soaking periods and an observed failure data for the plurality of battery packs.

10. The method of claim 9, further comprising dynamically updating the trained model as updated failure rate data is obtained.

11. A computer program product comprising, program instructions executable by a processor to cause the processor to perform a method comprising:
measuring a plurality of characteristics of a battery pack at a first time;
measuring the plurality of characteristics of the battery pack at a second time that is after the first time;
inputting the plurality of characteristics and a difference between the first time and the second time into a trained model for identifying anomalies;
determining, based on the trained model, whether the battery pack includes an anomaly; and
based on a determination that the battery pack includes the anomaly, flagging the battery pack as containing the anomaly.

12. The computer program product of claim 11, wherein the first time is after completion of a manufacturing of the battery pack.

13. The computer program product of claim 11, wherein the second time is before the battery pack is connected to an external load.

14. The computer program product of claim 11, wherein the plurality of characteristics of the battery pack include one or more of an average voltage of the battery pack, a voltage of each cell of the battery pack, an average temperature of the battery pack, and a voltage drop of cell of the battery pack.

15. The computer program product of claim 11, wherein the method further comprises computing one or more features for the battery pack based on the measured values and inputting the one or more features into the trained model.

16. The computer program product of claim 15, wherein the one or more features include one or more of an average voltage of the battery pack, a voltage range of the battery pack, a voltage drop over a natural soaking time for the battery pack, a rate of voltage drop over the natural soaking time for the battery pack, a change in a temperature of the battery pack over the natural soaking time, and a rate of change in the temperature of the battery pack over the natural soaking time.

17. The computer program product of claim 11, wherein the method further comprises identifying one or more cells of the battery pack that include the anomaly based on a determination that the battery pack includes the anomaly.

18. The computer program product of claim 17, wherein the method further comprises flagging the one or more cells of the battery pack that include the anomaly for inspection.

19. The method of claim 11, wherein the trained model for identifying anomalies is trained based on historical data regarding changes to the plurality of characteristics for a plurality of battery packs during corresponding natural soaking periods and an observed failure data for the plurality of battery packs.

20. The computer program product of claim 19, wherein the method further comprises dynamically updating the trained model as updated failure rate data is obtained.
